(19) United States
(12) Patent Application Publication
(10) Pub. No.: US 2025/0125247 A1
(43) Pub. Date: Apr. 17, 2025

(54) PANEL-LEVEL PACKAGED (PLP) INTEGRATED CIRCUITS AND METHODS OF MANUFACTURING THE SAME

(71) Applicant: Samsung Electronics Co., Ltd., Suwon-si (KR)

(72) Inventors: Jaeean Lee, Suwon-si (KR); Dongwon Kang, Suwon-si (KR); Jieun Park, Suwon-si (KR); Changyeon Song, Suwon-si (KR); Sunguk Lee, Suwon-si (KR)

(21) Appl. No.: 18/779,913

(22) Filed: Jul. 22, 2024

(30) Foreign Application Priority Data
Oct. 11, 2023 (KR) 10-2023-0135403

(51) Int. Cl. H01L 23/498; H01L 21/48; H01L 21/683; H01L 23/00; H01L 23/31; H01L 25/10

(52) U.S. Cl. CPC H01L 23/49838; H01L 23/3128; H01L 23/49822; H01L 23/49833; H01L 21/4857; H01L 21/486; H01L 21/6835; H01L 24/16; H01L 24/24; H01L 25/105; H01L 2224/16225; H01L 2224/24225; H01L 2225/1041; H01L 2924/1431; H01L 2924/1815

(57) ABSTRACT

An IC package includes a lower redistribution structure, a connection structure (with cavity) on the lower redistribution structure, a semiconductor chip in the cavity, a molding layer filling the cavity, covering the connection structure and the semiconductor chip, and having an upper through hole therein. An upper redistribution structure is provided that includes: an upper insulating layer on the molding layer, a first protrusion inside the upper through hole, and an upper redistribution pattern, which includes a first upper via pattern, inside the first protrusion. The upper through hole of the molding layer is located above the via structure of the connection structure, the first upper via pattern is electrically connected to the via structure of the connection structure, and a portion of the first upper line pattern of the upper redistribution structure is buried in the upper insulating layer.

### REFERENCE TO PRIORITY APPLICATION

This application claims priority under 35 U.S.C. § 119 to Korean Patent Application No. 10-2023-0135403, filed Oct. 11, 2023, the disclosure of which is hereby incorporated herein by reference.

### BACKGROUND

The inventive concept relates to integrated circuit packages and methods of manufacturing the same and, more specifically, to a panel-level integrated circuit packages and methods of manufacturing the same.

In the electronic products market, demand for portable devices is rapidly increasing, and as a result, there is a continuous demand for miniaturization and light-weight of electronic components mounted on the electronic products. In order to miniaturize and lighten electronic products, integrated circuit (IC) packages mounted on the electronic products are required to process a large amount of data while becoming smaller in volume. Recently, panel-level package (PLP) technology has been proposed, in which an IC package process is performed at a panel level; and, a panel-level semiconductor structure that has undergone the IC package process is separated into individual packages.

### SUMMARY

The inventive concept provides an integrated circuit package having detailed redistribution patterns therein, which extend within an upper redistribution structure.

The inventive concept provides an integrated circuit package having an upper redistribution structure therein, which includes heterogeneous insulating layers.

The problems to be solved by the technical spirit of the inventive concept are not limited to the problems mentioned above, and other problems not mentioned will be clearly understood by those skilled in the art from the following description.

According to an aspect of the inventive concept, there is provided an integrated circuit package including: a lower redistribution structure, a connection structure on the lower redistribution structure and having a cavity therein, a semiconductor chip on the lower redistribution structure and within the cavity of the connection structure, a molding layer in the cavity, covering the connection structure and an upper part of the semiconductor chip, and including an upper through hole extending inward from an upper surface thereof, and an upper redistribution structure including an upper insulating layer on the molding layer and including a first protrusion located inside the upper through hole and an upper redistribution pattern including a first upper via pattern located inside the first protrusion. In some embodiments, the upper through hole of the molding layer is above the via structure of the connection structure, the first upper via pattern is electrically connected to the via structure of the connection structure, and a portion of the first upper line pattern of the upper redistribution structure is buried in the upper insulating layer.

According to an aspect of the inventive concept, there is provided an integrated circuit package including: a lower redistribution structure, a connection structure on the lower redistribution structure and including a via structure, a semiconductor chip on the lower redistribution structure and horizontally spaced apart from the connection structure, a molding layer between the connection structure and the semiconductor chip, covering an upper part of the connection structure and the semiconductor chip, and including an upper through hole penetrating the upper surface of the molding layer, a third upper redistribution structure including a third upper redistribution pattern within the upper through hole and on the molding layer and electrically connected to the via structure, and a third upper insulating layer covering the third upper redistribution pattern, a first upper redistribution structure including a first upper insulating layer on the third upper redistribution structure, and a first upper redistribution pattern on the first upper insulating layer, and a second upper redistribution structure including a second upper insulating layer on the first upper insulating layer, and a second upper redistribution pattern on the second upper insulating layer. According to some embodiments, the constituent material of the third upper insulating layer is different from the constituent material of the first upper insulating layer and the second upper insulating layer, the third upper insulating layer of the third upper redistribution structure includes a third through hole, the first upper insulating layer of the first upper redistribution structure further includes a first protrusion located in the third through hole, and the first upper redistribution pattern of the first upper redistribution structure further includes a first upper via pattern surrounded by the first protrusion.

According to another aspect of the inventive concept, there is provided an integrated circuit package including: a lower redistribution structure, a connection structure on an upper surface of the lower redistribution structure, including a via structure, and having a cavity, a lower semiconductor chip located on the upper surface of the lower redistribution structure and within the cavity of the connection structure, a molding layer between the connection structure and the lower semiconductor chip in the cavity, covering an upper part of the connection structure and the lower semiconductor chip, and including an upper through hole extending inward from the upper surface thereof, a third upper redistribution structure including a third upper redistribution pattern on the molding layer and within the upper through hole and electrically connected to the via structure, and a third upper insulating layer covering the third upper redistribution pattern, a first upper redistribution structure including a first upper insulating layer on the third upper redistribution structure, and a first upper redistribution pattern on the first upper insulating layer, a second upper redistribution structure including a second upper insulating layer on the first upper insulating layer, and a second upper redistribution pattern on the second upper insulating layer, an upper passivation layer on the second upper redistribution structure and including an opening that exposes a portion of the second upper redistribution pattern of the second upper redistribution structure, and an upper semiconductor chip mounted on the upper passivation layer and electrically connected to the second upper redistribution structure. According to some embodiments, the constituent material of the third upper insulating layer is different from the constituent material of the first and second upper insulating layers, the third upper insulating layer of the third upper redistribution structure includes a third through hole, the first upper insulating layer of the first upper redistribution structure further includes a first protrusion located in the third through hole, and the first upper redistribution pattern of the first upper redistribution structure further includes a first upper via pattern surrounded by the first protrusion.

### BRIEF DESCRIPTION OF THE DRAWINGS

Embodiments will be more clearly understood from the following detailed description taken in conjunction with the accompanying drawings in which:

FIG. 1 is a schematic cross-sectional view of an integrated circuit package according to an embodiment;

FIG. 2 is a schematic enlarged view of a portion “EX1” of the integrated circuit package in FIG. 1;

FIG. 3 is a schematic enlarged view of the portion “EX1” of the integrated circuit package in FIG. 1;

FIG. 4 is a schematic cross-sectional view of an integrated circuit package according to an embodiment;

FIG. 5 is a schematic cross-sectional view of an integrated circuit package according to an embodiment;

FIG. 6 is a schematic enlarged view of a portion “EX2” of the integrated circuit package in FIG. 5; and

FIGS. 7 to 21 are diagrams showing a method of manufacturing an integrated circuit package according to a process sequence according to an embodiment.

### DETAILED DESCRIPTION OF EMBODIMENTS

The inventive concept may be modified into various forms and may have various embodiments. In this regard, the inventive concept will now be made in detail to embodiments, examples of which are illustrated in the accompanying drawings. However, there is no intent to limit embodiments to the particular forms disclosed,

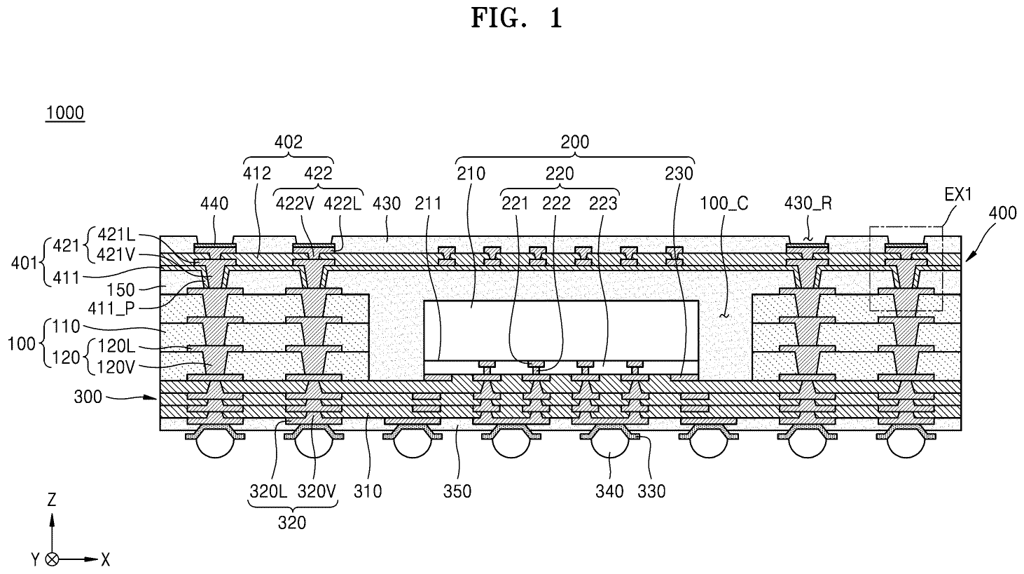

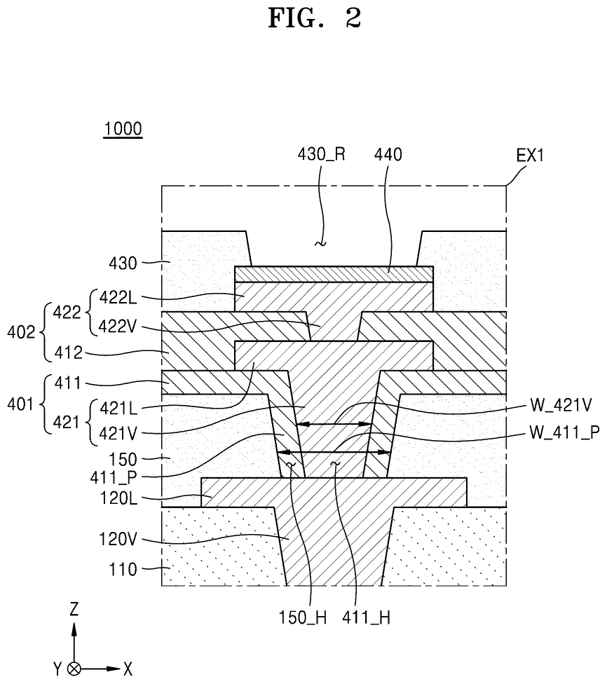

FIG. 1 is a schematic cross-sectional view of an integrated circuit package 1000 according to an embodiment; and FIG. 2 is a schematic enlarged view of a portion “EX1” of the integrated circuit package 1000 of FIG. 1. Referring to FIGS. 1 and 2, the integrated circuit package 1000 includes a lower redistribution structure 300, a connection structure 100, a semiconductor chip 200, a molding layer 150, and an upper redistribution structure 400.

Hereinafter, unless specifically defined, a direction parallel to an upper surface of the lower redistribution structure 300 is defined as a first direction (X direction), a direction perpendicular to the upper surface of the lower redistribution structure 300 is defined as a vertical direction (Z direction), and a direction perpendicular to the first direction (X direction) and the vertical direction (Z direction) is defined as a second direction (Y direction). A direction in which the first direction (X direction) and the second direction (Y direction) are combined is defined as a horizontal direction.

The connection structure 100 of the integrated circuit package 1000 may be on the lower redistribution structure 300. For example, the connection structure 100 may be electrically connected to a portion of the lower redistribution pattern 320 of the lower redistribution structure 300. The connection structure 100 may electrically connect the upper redistribution structure 400 to the lower redistribution structure 300.

The connection structure 100 may include a cavity 100_C extending from an upper surface to a lower surface thereof. The semiconductor chip 200 may be mounted inside the cavity 100_C of the connection structure 100. The cavity 100_C may be formed in the center of the connection structure 100 as shown in FIG. 1, but the number and arrangement of the cavities 100_C are not limited to those shown.

The connection structure 100 may include a plurality of base layers 110 and via structures 120. In some embodiments, the plurality of base layers 110 may include first to third base layers stacked in the vertical direction (Z direction). For example, the connection structure 100 may have a multi-layer structure including the first base layer to the third base layer. The plurality of base layers 110 may surround at least a portion of the via structure 120. In example embodiments, the plurality of base layers 110 may each include a thermosetting resin, such as a phenolic resin and an epoxy resin, a thermoplastic resin, such as a polyimide, or an insulating material in which at least one resin selected from the resins above is impregnated into a core material including inorganic filler and/or glass fiber. For example, the plurality of base layers 110 may each include prepreg, Ajinomoto build-up film (ABF), Frame Retardant 4 (FR4), tetrafunctional epoxy, polyphenylene ether, bismaleimide triazine (BT), epoxy/polyphenylene oxide, Thermount, cyanate ester, polyimide, liquid crystal polymer, or a combination of these materials.

A via structure 120 may include a plurality of connection pads 120L and a plurality of connection vias 120V. The plurality of connection pads 120L may extend in the horizontal direction on top or bottom surfaces of each of the plurality of base layers 110. In some embodiments, the plurality of connection pads 120L may include first to fourth connection pads located at different vertical levels. The first connection pads located lowermost among the plurality of connection pads 120L may be connected to the lower redistribution structure 300, and the fourth connection pads located uppermost among the plurality of connection pads 120L may be connected to the upper redistribution structure 400.

The plurality of connection vias 120V may extend vertically within the plurality of base layers 110. The plurality of connection vias 120V may connect the plurality of connection pads 120L located at different vertical levels to one another. In some embodiments, the plurality of connection vias 120V may include first to third connection vias located at different vertical levels. In example embodiments, the plurality of connection pads 120L may each include electrolytically deposited (ED) copper foil, rolled-annealed (RA) copper foil, stainless steel foil, aluminum foil, ultra-thin copper foil, sputtered copper, or copper alloys. In example embodiments, the plurality of connection vias 120V may each include copper, nickel, stainless steel, beryllium copper, or a combination thereof.

The semiconductor chip 200 of the integrated circuit package 1000 may be located on the lower redistribution structure 300. The semiconductor chip 200 may be mounted within the cavity 100_C of the connection structure 100 spaced apart from an inner wall of the cavity 100_C. In FIG. 1, the integrated circuit package 1000 is shown to include one semiconductor chip 200, but the number of semiconductor chips 200 is not limited thereto. In some embodiments, the semiconductor chip 200 may be referred to as a lower semiconductor chip.

The semiconductor chip 200 may include a semiconductor substrate 210 and a wiring structure 220. The semiconductor substrate 210 may include an active surface 211 and an inactive surface facing the active surface 211. The wiring structure 220 may be formed on the active surface 211 of the semiconductor substrate 210. The semiconductor chip 200 may be on the lower redistribution structure 300 such that the active surface 211 of the semiconductor substrate 210 faces the lower redistribution structure 300. For example, the semiconductor chip 200 may be on the lower redistribution structure 300 in a face-down (e.g., flip-chip) manner. In this case, the inactive surface of the semiconductor chip 200 may be referred to as an upper surface of the semiconductor chip 200 and a surface opposite to the inactive surface of the semiconductor chip 200 may be referred to as a lower surface of the semiconductor chip 200 of the semiconductor substrate 210.

For example, the semiconductor substrate 210 may include a semiconductor material, such as silicon (Si) or germanium (Ge). Alternatively, the semiconductor substrate 210 may include a compound semiconductor material, such as silicon carbide (SiC), gallium arsenide (GaAs), indium arsenide (InAs), and indium phosphide (InP). The semiconductor substrate 210 may include a well doped with an impurity, which is a conductive region. The semiconductor substrate 210 may have various device isolation structures, such as a shallow trench isolation (STI) structure.

A semiconductor device including a plurality of various types of individual devices may be formed on the active surface 211 of the semiconductor substrate 210. The plurality of individual devices may be electrically connected to the conductive region of the semiconductor substrate 210. The semiconductor device may further include a conductive wire or a conductive plug that electrically connects the plurality of individual devices to the conductive region of the semiconductor substrate 210. Additionally, each of the plurality of individual devices may be electrically separated from other neighboring individual devices by an insulating film.

In some embodiments, the semiconductor chip 200 may include a logic element. For example, the semiconductor chip 200 may be a central processing unit chip, a graphics processing unit chip, or an application processor (AP). In other embodiments, if the integrated circuit package 1000 includes a plurality of semiconductor chips 200, one of the plurality of semiconductor chips 200 may be a central processing unit chip, a graphics processing unit chip, or an AP chip, and the other one may be a memory semiconductor chip including a memory element.

For example, the memory device may include a non-volatile memory device, such as flash memory, phase-change random access memory (PRAM), magnetoresistive random access memory (MRAM), ferroelectric random access memory (FeRAM), or resistive random access memory (RRAM). In some embodiments, the memory device may include a volatile memory device, such as Dynamic Random Access Memory (DRAM) or Static Random Access Memory (SRAM).

The wiring structure 220 of the semiconductor chip 200 may include a plurality of wiring line patterns 221, a plurality of wiring via patterns 222 connected to the plurality of wiring line patterns 221, and a wiring insulating layer 223 surrounding the plurality of wiring line patterns 221 and the plurality of wiring via patterns 222. In some embodiments, the wiring structure 220 may have a multi-layer wiring structure including the wiring line patterns 221 and the wiring via patterns 222 located at different vertical levels.

In some embodiments, the semiconductor chip 200 may further include a lower pad 230. The lower pad 230 may be on a lower surface of the wiring structure 220 and may be electrically connected to the wiring line pattern 221 and/or the wiring via pattern 222. For example, the lower pad 230 may include a conductive material, for example, aluminum (Al). The semiconductor chip 200 may be electrically connected to a lower redistribution pattern 320 of the lower redistribution structure 300 through the lower pad 230.

The lower redistribution structure 300 of the integrated circuit package 1000 may extend input/output terminals of the semiconductor chip 200 to an outer region of the semiconductor chip 200. The lower redistribution structure 300 may include a plurality of lower insulating layers 310 and the lower redistribution pattern 320 including a lower via pattern 320V and a lower line pattern 320L. The number and arrangement of the lower insulating layers 310, the lower via patterns 320V, and the lower line patterns 320L constituting the lower redistribution structure 300 are not limited to those shown in the drawing and may vary in various embodiments.

The lower insulating layers 310 may include an insulating material, for example, a photo-imageable dielectric (PID) resin. In this case, the lower insulating layers 310 may further include an inorganic filler. The lower insulating layers 310 may include the same or different materials.

The lower redistribution pattern 320 including the lower via pattern 320V and the lower line pattern 320L may expand the input/output terminals of the semiconductor chip 200 to the outside. The lower line pattern 320L may be on at least one of upper and lower surfaces of the lower insulating layers 310. The lower via pattern 320V may be connected to a portion of the lower line patterns 320L by penetrating the lower insulating layers 310.

The lower via pattern 320V may be completely filled with a conductive material, or may have a shape in which the conductive material is formed along a wall of the via. The lower redistribution pattern 320 may include a conductive material, such as copper (Cu), aluminum (Al), silver (Ag), tin (Sn), gold (Au), nickel (Ni), lead (Pb), titanium (Ti), or an alloy thereof.

The lower surface of the semiconductor chip 200 may be in direct contact with the uppermost lower insulating layer 310 among the lower insulating layers 310. In some embodiments, the lower redistribution structure 300 may be formed on the lower surface of the semiconductor chip 200 through a chip-first process. According to a sequence of forming the lower redistribution structure 300, the lower via pattern 320V may have a tapered shape in which a horizontal width increases as the distance from the semiconductor chip 200 increases.

In some embodiments, the integrated circuit package 1000 may further include a lower passivation layer 350. The lower passivation layer 350 is disposed on a lower surface of the lower redistribution structure 300 and may protect the lower redistribution structure 300. The lower passivation layer 350 may include an insulating material, for example, a thermosetting resin or a thermoplastic resin, but is not limited thereto.

For example, at least a portion of the lower line pattern 320L may be exposed through openings of the lower passivation layer 350. The exposed lower line pattern 320L may be electrically connected to lower pads 330 disposed inside the openings of the lower passivation layer 350. External connection terminals 340 may be electrically connected to the lower pads 330, respectively.

The external connection terminals 340 may connect the integrated circuit package 1000 to a main board of a separate electronic device on which the integrated circuit package 1000 is mounted. The external connection terminals 340 may include at least one of a conductive material, for example, solder, tin (Sn), silver (Ag), copper (Cu), and aluminum (Al). The external connection terminals 340 may have various shapes, such as land, bump, pillar, or pin, in addition to a ball shape.

The molding layer 150 of the integrated circuit package 1000 is located between the connection structure 100 and the semiconductor chip 200 in the cavity 100_C and may cover upper surfaces of each of the connection structure 100 and the semiconductor chip 200. The molding layer 150 may include an epoxy-based material, a thermosetting material, or a thermoplastic material. For example, the molding layer 150 may include ABF Film, FR-4, BT, Epoxy Molding Compound (EMC), etc. The molding layer 150 may include a plurality of upper through holes 150_H extending inward from an upper surface of the molding layer 150. Through the plurality of upper through holes 150_H, the uppermost connection pad 120L among the plurality of connection pads 120L of the connection structure 100 may be exposed to the outside For example, each of the plurality of upper through holes 150_H may be located on top of the plurality of connection pads 120L of the connection structure 100.

The upper redistribution structure 400 of the integrated circuit package 1000 may be formed as a multi-layer structure. In some embodiments, the upper redistribution structure 400 may include a first upper redistribution structure 401 and a second upper redistribution structure 402. The upper redistribution structure 400 may extend input/output terminals of a semiconductor chip (not shown) mounted on the upper redistribution structure 400 to the outside.

A first upper insulating layer 411 may cover an upper part of the molding layer 150. The first upper insulating layer 411 may include a first protrusion 411_P extending downward from a lower surface of the first upper insulating layer 411. The first protrusion 411_P of the first upper insulating layer 411 may be located within the upper through hole 150_H of the molding layer 150. The first upper insulating layer 411 may include a first through hole 411_H extending from an upper surface to a lower surface of the first upper insulating layer 411. The first through hole 411_H may be located inside the first protrusion 411_P. Accordingly, the first through hole 411_H may be located inside the upper through hole 150_H.

In some embodiments, the central axis of the first protrusion 411_P may coincide with the central axis of the upper through hole 150_H. For example, the center of the upper through hole 150_H may coincide with the center of the first through hole 411_H. That is, when upper surfaces of the upper through hole 150_H and the first through hole 411_H have a circular shape, the upper surfaces of the upper through hole 150_H and the first through hole 411_H may be concentric circles.

In some embodiments, each of the plurality of upper through holes 150_H of the molding layer 150 may overlap the via structure 120 of the connection structure 100 in a vertical direction. The first through hole 411_H located inside the upper through hole 150_H may overlap the via structure 120 in the vertical direction. Accordingly, at least a portion of the via structure 120 of the connection structure 100 may be exposed to the outside through the first through hole 411_H.

A first upper redistribution pattern 421 of the first upper redistribution structure 401 may include a first upper line pattern 421L and a first upper via pattern 421V. The first upper line pattern 421L may be located on the first upper insulating layer 411. For example, a portion of the first upper line pattern 421L may be buried by the first upper insulating layer 411 and the second upper insulating layer 412. That is, a portion of the first upper line pattern 421L may be buried inside the upper insulating layer.

The first upper via pattern 421V may be located inside the first protrusion 411_P. The first upper via pattern 421V may extend in the vertical direction (Z direction) from the first upper line pattern 421L. For example, the first upper via pattern 421V may be located in the first through hole 411_H of the first upper insulating layer 411 and may be electrically connected to the plurality of connection pads 120L of the via structure 120.

In some embodiments, a horizontal width W_411_P of the first protrusion 411_P may be greater than a horizontal width W_421V of the first upper via pattern 421V. In some embodiments, a horizontal width W_411_P of the first protrusion 411_P may be greater than a horizontal width W_421V of the first upper via pattern 421V. The horizontal width W_411_P of the first protrusion 411_P may be in a range from about 50 μm to about 60 μm, and the horizontal width W_421V of the first upper via pattern 421V may be in a range from about 10 μm to about 20 μm. In the present specification, the “horizontal width” may denote a length in a first direction (X direction) and/or a length in a second direction (Y direction).

In some embodiments, the first upper via pattern 421V and the first upper insulating layer 411 may be located in the upper through hole 150_H. For example, the first upper via pattern 421V may be spaced apart from the molding layer 150 that defines the upper through hole 150_H with the first upper insulating layer 411 therebetween.

In some embodiments, the constituent material of the first upper insulating layer 411 may be different from the constituent material of the molding layer 150. The first upper insulating layer 411 may include an insulating material, for example, a PID resin. In this case, the first upper insulating layer 411 may further include an inorganic filler. In some embodiments, the constituent material of the first upper insulating layer 411 may be different from the constituent material of the molding layer 150. For example, the first upper insulating layer 411 may include a photosensitive material, and the molding layer 150 may include a thermosetting resin. In one embodiment, the first upper insulating layer 411 may include a PID resin, and the molding layer 150 may include ABF.

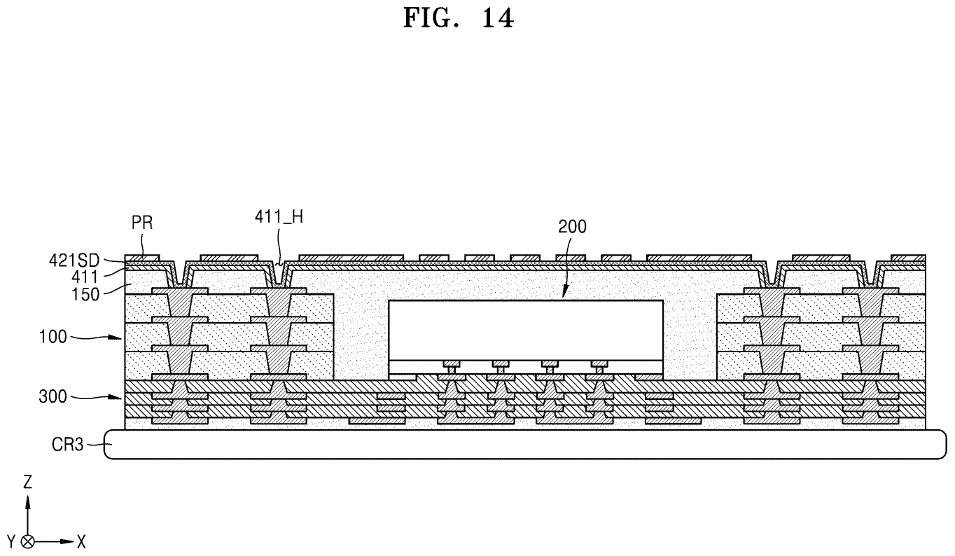

For example, the first upper insulating layer 411 may include a PID resin, and a seed layer (421SD in FIG. 14), which is a basis of the first upper redistribution pattern 421, may be formed through a sputtering process. Compared to a case when the seed layer is formed through electroless plating, the seed layer may be formed with a less line width. Accordingly, the first upper redistribution pattern 421 may have a relatively small line width/line spacing.

The second upper redistribution structure 402 of the integrated circuit package 1000 may include a second upper insulating layer 412 and a second upper redistribution pattern 422. The second upper insulating layer 412 may be located on the first upper redistribution structure 401. For example, the second upper insulating layer 412 may cover an upper surface of the first upper redistribution structure 401.

The second upper redistribution pattern 422 may include a second upper line pattern 422L and a second upper via pattern 422V extending in the vertical direction (Z direction) from the second upper line pattern 422L. The second upper line pattern 422L may be located on the second upper insulating layer 412. The second upper via pattern 422V may penetrate the second upper insulating layer 412 and extend in the vertical direction (Z direction). The second upper via pattern 422V may electrically connect the first upper line pattern 421L to the second upper line pattern 422L. A metal plating layer 440 may be provided on at least a portion of the second upper line pattern 422L. The metal plating layer 440 may include a metal including, for example, gold (Au).

In some embodiments, the second upper insulating layer 412 may include an insulating material, for example, a PID resin. In this case, the second upper insulating layer 412 may further include an inorganic filler.

In some embodiments, the first upper redistribution pattern 421 and the second upper redistribution pattern 422 may be referred to as upper redistribution patterns, and the first upper insulating layer 411 and the second upper insulating layer 412 may be referred to as upper insulating layers. In some embodiments, an interface between the upper insulating layers of the upper redistribution structure 400 may not exist. That is, the interface between the first upper insulating layer 411 of the first upper redistribution structure 401 and the second upper insulating layer 412 of the second upper redistribution structure 402 may not exist.

In some embodiments, the constituent materials of the second upper insulating layer 412 and the first upper insulating layer 411 may be substantially the same. For example, the first upper insulating layer 411 and the second upper insulating layer 412 may include a PID resin, and a seed layer that is a basis of each of the first upper redistribution pattern 421 and the second upper redistribution pattern 422 may be formed through a sputtering process, and thus, the seed layer may have a relatively small line width/line spacing.

In some embodiments, the integrated circuit package 1000 may further include an upper passivation layer 430. The upper passivation layer 430 may be on the second upper redistribution structure 402 and may protect the upper redistribution structure 400. The upper passivation layer 430 may include an insulating material, for example, a thermosetting resin or a photosensitive material, but is not limited thereto.

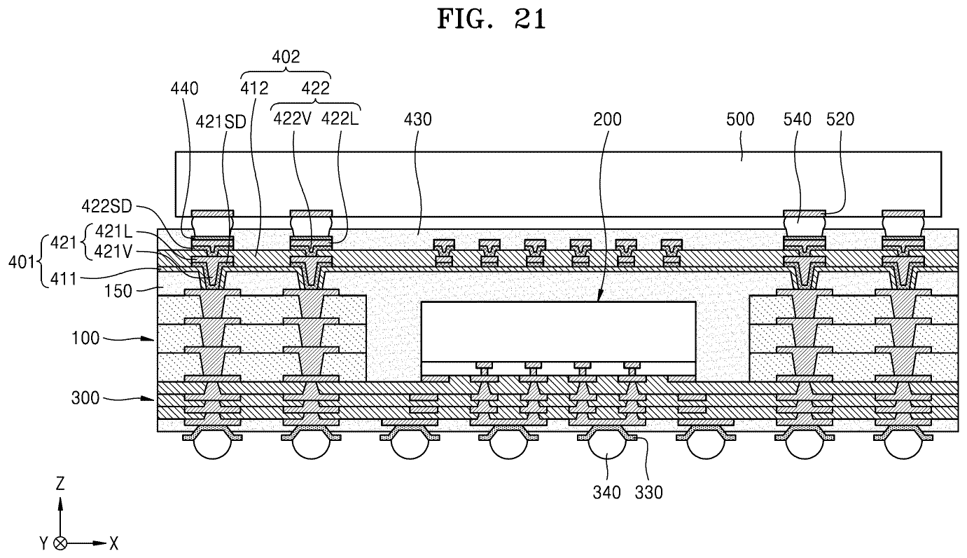

The upper passivation layer 430, through which at least a portion of the second upper line pattern 422L and the metal plating layer 440 are exposed, may have a partially recessed opening 430_R. In the opening 430_R, upper connection terminals 540 (refer to FIG. 21) may be located in a package on package (PoP)-type package in which a semiconductor chip 500 (refer to FIG. 21) is stacked or attached to the upper redistribution structure 400.

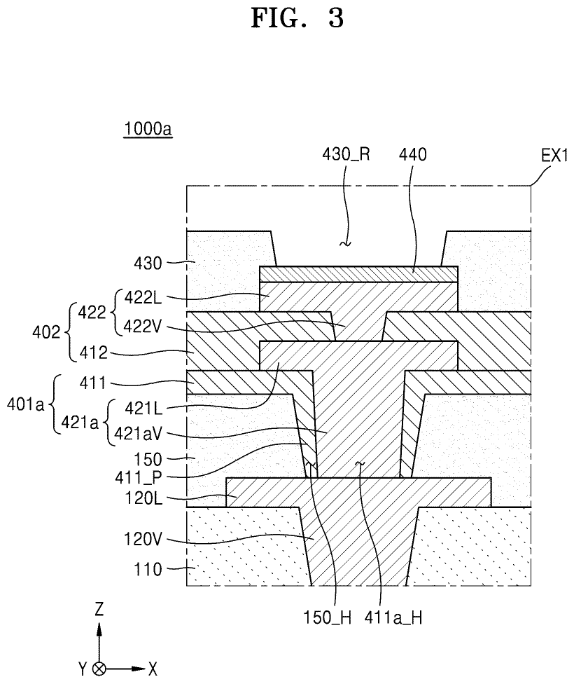

FIG. 3 is a schematic enlarged view of the portion “EX1” of an integrated circuit package 1000 in FIG. 1. Most of components constituting an integrated circuit package 1000a described below and the materials of the components are substantially the same or similar to those previously described with reference to FIG. 1. Therefore, for convenience of explanation, the description will focus on the differences between the integrated circuit package 1000a of FIG. 3 and the integrated circuit package 1000 of FIG. 1 described above.

Referring to FIG. 3 together with FIGS. 1 and 2, the first upper redistribution structure 401 and the molding layer 150 of the integrated circuit package 1000a will be described in detail. The molding layer 150 of the integrated circuit package 1000a may include an upper through hole 150_H extending from top to bottom of the molding layer 150. The horizontal width of the upper through hole 150_H may narrow and extend towards the connection structure 100. That is, the upper through hole 150_H may have a tapered shape. In other words, a side wall of the molding layer 150 forming the upper through hole 150_H may be inclined in the vertical direction (Z direction) with respect to an upper surface of the connection structure 100.

The first upper redistribution structure 401a of the integrated circuit package 1000a may include a first upper insulating layer 411 and a first upper redistribution pattern 421a. The first upper insulating layer 411 may include a first through hole 411a_H extending from an upper surface to a lower surface of the first upper insulating layer 411. The horizontal width of the first through hole 411a_H may narrow and extend towards the connection structure 100. That is, the first through hole 411a_H may have a tapered shape. In other words, a sidewall of the first upper insulating layer 411 forming the first through hole 411a_H may be inclined in the vertical direction (Z direction) with respect to an upper surface of the molding layer 150.

In some embodiments, the slope of the upper through hole 150_H may be different from the slope of the first through hole 411a_H. For example, the upper through hole 150_H may be formed through a laser drilling process, and the first through hole 411a_H may be formed through a photo process. Therefore, the slopes of the upper through hole 150_H and the first through hole 411a_H may be different. In the present specification, the “slope” refers to an angle formed by the sidewall forming the hole with a reference surface, for example, an upper surface of the connection structure 100.

In some embodiments, the slope of the upper through hole 150_H may be less than the slope of the first through hole 411a_H. For example, if upper surfaces of the first through hole 411a_H and the upper through hole 150_H are concentric, a region of the first upper insulating layer 411 located inside the upper through hole 150_H may have a smaller length in a radial direction towards the connection structure 100. That is, the separation distance between the sidewall of the molding layer 150, which forms the upper through hole 150_H, and the first upper via pattern 421aV decreases towards the connection structure 100.

A slope of a side surface of the first protrusion 411_P of the first upper insulating layer 411 may be different from the slope of a side surface of the first upper via pattern 421aV located in the first through hole 411a_H. In some embodiments, the slope of the side surface of the first upper via pattern 421aV may be less than the slope of the side surface of the first protrusion 411_P of the first upper insulating layer 411.

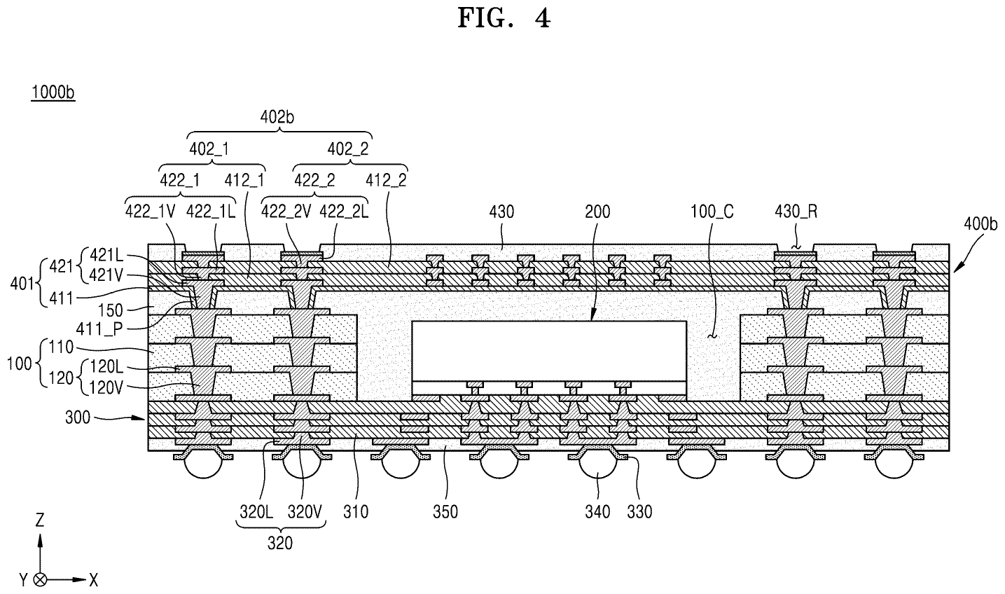

FIG. 4 is a schematic cross-sectional view of an integrated circuit package 1000b according to another embodiment. Most of components constituting the integrated circuit package 1000b described below and materials of the components are substantially the same or similar to those previously described with reference FIG. 1. Therefore, for convenience of explanation, the description will focus on the differences between the integrated circuit package 1000a of FIG. 4 and the integrated circuit package 1000 of FIG. 1 described above.

The integrated circuit package 1000b may include an upper redistribution structure 400b. The upper redistribution structure 400b may include a first upper redistribution structure 401 and a second upper redistribution structure 402b. In some embodiments, the second upper redistribution structure 402b may have a multi-layer structure. For example, the second upper redistribution structure 402b may include a first layer redistribution structure 402_1 and a second layer redistribution structure 402_2. The second layer redistribution structure 402_2 may be stacked on the first layer redistribution structure 402_1. However, the number of layers of the second layer redistribution structure 402_2 is not limited thereto.

For example, each of the first layer redistribution structure 402_1 and the second layer redistribution structure 402_2 may be the second upper redistribution structure 402 (refer to FIG. 1) described above. However, the first layer redistribution structure 402_1 may be electrically connected to the first upper redistribution structure 401, and the second layer redistribution structure 402_2 may be in contact with the upper passivation layer 430.

Specifically, the first layer redistribution structure 402_1 may include a first layer insulating layer 412_1 and a first layer redistribution pattern 422_1. The second layer redistribution structure 402_2 may include a second layer insulating layer 412_2 and a second layer redistribution pattern 422_2. The first layer redistribution pattern 422_1 includes a first layer line pattern 422_1L and a first layer via pattern 422_1V, and the second layer redistribution pattern 422_2 includes a second layer line pattern 422_2L and a second layer via pattern 422_2V.

The first layer line pattern 422_1L is located on the first layer insulating layer 412_1 and a portion of the first layer line pattern 422_1L may be covered by the second layer insulating layer 412_2, and the second layer line pattern 422_2L is located on the second layer insulating layer 412_2, and a portion of the second layer line pattern 422_2L may be covered by the upper passivation layer 430. The first layer via pattern 422_1V may electrically connect the first layer line pattern 422_1L to the plurality of connection pads 120L of the connection structure 100, and the second layer via pattern 422_2V may electrically connect the second layer line pattern 422_2L to the first layer line pattern 422_1L.

A vertical level of the first layer line pattern 422_1L may be different from a vertical level of the second layer line pattern 422_2L. The vertical level of the first layer line pattern 422_1L may be less than the vertical level of the second layer line pattern 422_2L. In the present specification, the vertical level refers to a distance spaced apart from a lower surface of the lower redistribution structure 300.

In some embodiments, the vertical level of the first upper line pattern 421L may be less than the vertical level of the first layer line pattern 422_1L. Among the upper redistribution patterns, the first layer line pattern 422_1L and the first upper line pattern 421L may be line patterns buried by an upper insulating layer. That is, the upper redistribution structure 400 may be a multi-layer structure with three or more layers.

For example, some of the upper line patterns may be completely buried in an upper insulating layer. The upper line patterns completely buried in the upper insulating layer may have different vertical levels from each other.

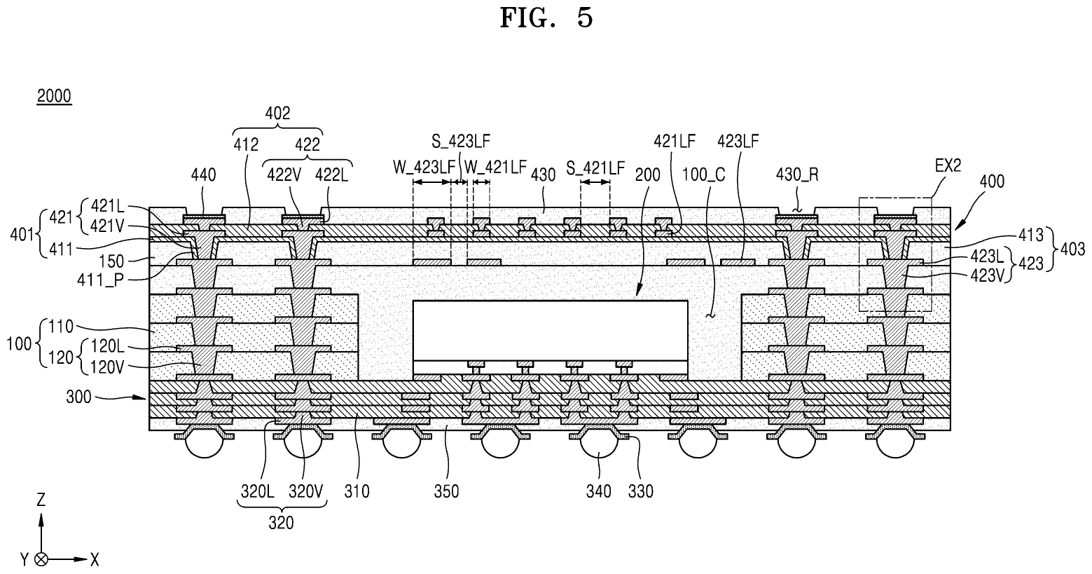

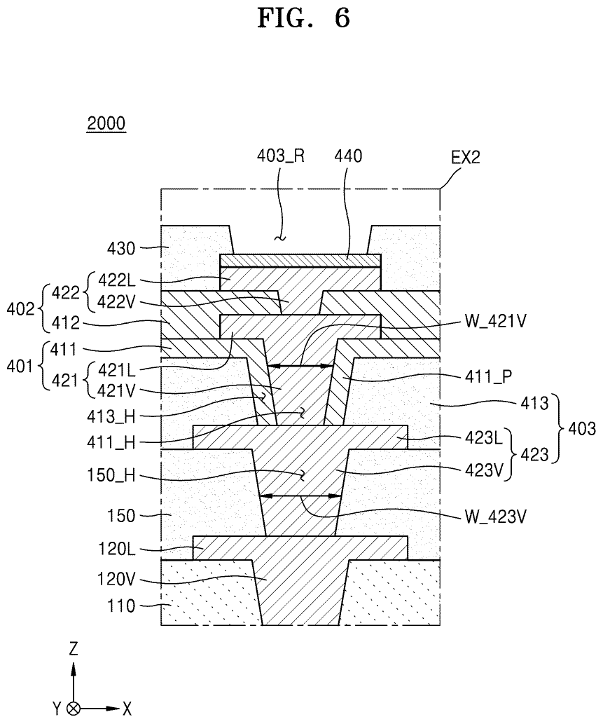

FIG. 5 is a schematic cross-sectional view of an integrated circuit package 2000 according to an embodiment. FIG. 6 is a schematic enlarged view of the portion “EX2” of the integrated circuit package 2000 of FIG. 5. Most of components constituting the integrated circuit package 2000 described below and the materials of the components are substantially the same or similar to those previously described with reference to FIG. 1. Therefore, for convenience of explanation, the description will focus on the differences between the integrated circuit package 2000 of FIG. 5 and the integrated circuit package 1000 of FIG. 1 described above.

Referring to FIGS. 5 and 6, the upper redistribution structure 400 of the integrated circuit package 2000 may further include a third upper redistribution structure 403. The third upper redistribution structure 403 may be the lowest layer of the upper redistribution structure 400 having a multi-layer structure. The third upper redistribution structure 403 of the integrated circuit package 2000 may be located between the molding layer 150 and the first upper redistribution structure 401. That is, the molding layer 150, the third upper redistribution structure 403, and the first upper redistribution structure 401 may be sequentially stacked. The third upper redistribution structure 403 may be electrically connected to the connection structure 100, and the first upper redistribution structure 401 may be electrically connected to the third upper redistribution structure 403.

The third upper redistribution structure 403 may include a third upper redistribution pattern 423 and a third upper insulating layer 413. The third upper redistribution pattern 423 may be located inside the upper through hole 150_H of the molding layer 150 and on the molding layer 150. For example, the third upper redistribution pattern 423 may include a third upper via pattern 423V located inside the upper through hole 150_H and a third upper line pattern 423L located on the upper molding layer 150. The third upper insulating layer 413 may be located on the molding layer 150 and may cover the third upper redistribution pattern 423. The third upper insulating layer 413 may include a third through hole 413_H. A horizontal width of the third through-hole 413_H may decrease towards the third upper redistribution pattern 423.

The first upper redistribution structure 401 may include a first upper redistribution pattern 421 and a first upper insulating layer 411. The first upper insulating layer 411 may cover the third upper redistribution structure 403. For example, a first protrusion 411_P of the first upper insulating layer 411 may be located inside the third through hole 413_H of the third upper insulating layer 413.

The first upper insulating layer 411 may include a first through hole 411_H extending from an upper surface to a lower surface of the first upper insulating layer 411. In some embodiments, a horizontal width of the first through hole 411_H may decrease towards the third upper redistribution pattern 423. The first through hole 411_H may be located in the first protrusion 411_P. That is, the first through hole 411_H may be located inside the third through hole 413_H. In some embodiments, when the first through hole 411_H and the third through hole 413_H have a cylindrical shape, the central axis of the first through hole 411_H may coincide with the central axis of the third through hole 413_H. In some embodiments, a horizontal width of the first through hole 411_H may be less than a horizontal width of the third through hole 413_H. That is, a sidewall of the third upper insulating layer 413 forming the third through hole 413_H may be completely covered by the first upper insulating layer 411. For example, the horizontal width of the third through hole 413_H may be in a range from about 50 μm to about 60 μm, and the horizontal width of the first through hole 411_H may be in a range from about 10 μm to about 20 μm.

The first upper redistribution pattern 421 of the first upper redistribution structure 401 may include a first upper line pattern 421L and a first upper via pattern 421V. The first upper line pattern 421L may be located on the first upper insulating layer 411, and the first upper via pattern 421V may be located in the first through hole 411_H. For example, a portion of the first upper line pattern 421L may be located above the first through hole 411_H and electrically connected to the first upper via pattern 421V. For example, the first upper line pattern 421L and the first upper via pattern 421V may be formed in the same process to form one body; and, the first upper via pattern 421V is located inside the first through hole 411_H and may be spaced apart from the third upper insulating layer 413 in the horizontal direction with the first upper insulating layer 411 therebetween. In some embodiments, a side surface of the first upper via pattern 421V may be completely covered by the first upper insulating layer 411.

In some embodiments, the molding layer 150 and the third upper insulating layer 413 may include substantially the same material. For example, the molding layer 150 and the third upper insulating layer 413 may include at least one of a thermosetting resin and a thermoplastic resin. For example, the molding layer 150 and the third upper insulating layer 413 may include ABF, FR-4, BT, EMC, etc.

In some embodiments, the horizontal width of the upper through hole 150_H of the molding layer 150 may be substantially equal to the horizontal width of the third through hole 413_H of the third upper insulating layer 413. For example, a slope of the upper through hole 150_H and a slope of the third through hole 413_H may be substantially the same. For example, the upper through hole 150_H and the third through hole 413_H may be formed by a laser drilling process, and thus, the horizontal width and slope of the upper through hole 150_H and the third through hole 413_H may be the same.

In some embodiments, a slope of a side of the first protrusion 411_P of the first upper insulating layer 411 may be the same as a slope of the third upper via pattern 423V of the third upper redistribution structure 403. In some embodiments, a horizontal width W_421V of the first upper via pattern 421V may be less than a horizontal width W_423V of the third upper via pattern 423V. For example, the horizontal width W_423V of the third upper via pattern 423V may be in a range from about 50 μm to about 60 μm, and the horizontal width W_421V of the first upper via pattern 421V may be in a range from about 10 μm to about 20 μm.

In some embodiments, a pattern having the smallest linewidth among the first upper line patterns 421L may be referred to as a first fine line pattern 421LF, and the minimum separation distance between the two adjacent first upper line patterns 421L may be referred to as a first line spacing S_421LF. Among the third upper line patterns 423L, a pattern having the smallest linewidth is referred to as a third fine line pattern 423LF, and the minimum separation distance between the two adjacent third upper line patterns 423L may be referred to as a third line spacing S_423LF. For example, a first linewidth W_421LF of the first fine line pattern 421LF may be less than a third linewidth W_423LF of the third fine line pattern 423LF. The first line spacing S_421LF may be less than the third line spacing S_423LF. In some embodiments, the third linewidth W_423LF of the third fine line pattern 423LF may be 25 μm or less, the third line spacing S_423LF may be 25 μm or less, the first linewidth W_421LF of the first fine line pattern 421LF may be 9 μm or less, and the first line spacing S_421LF may be 12 μm or less. In some embodiments, the third linewidth W_423LF may be 15 μm or more and 25 μm or less, the third line spacing S_423LF may be 15 μm or more and 25 μm or less, the first linewidth W_421LF may be 3 μm or more and 9 μm or less, and the first line spacing S_421LF may be 3 μm or more and 12 μm or less.

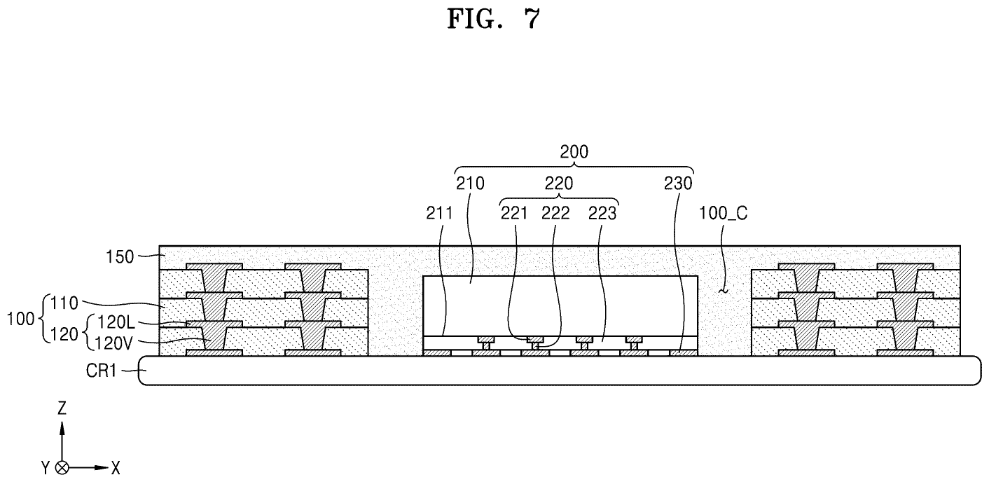

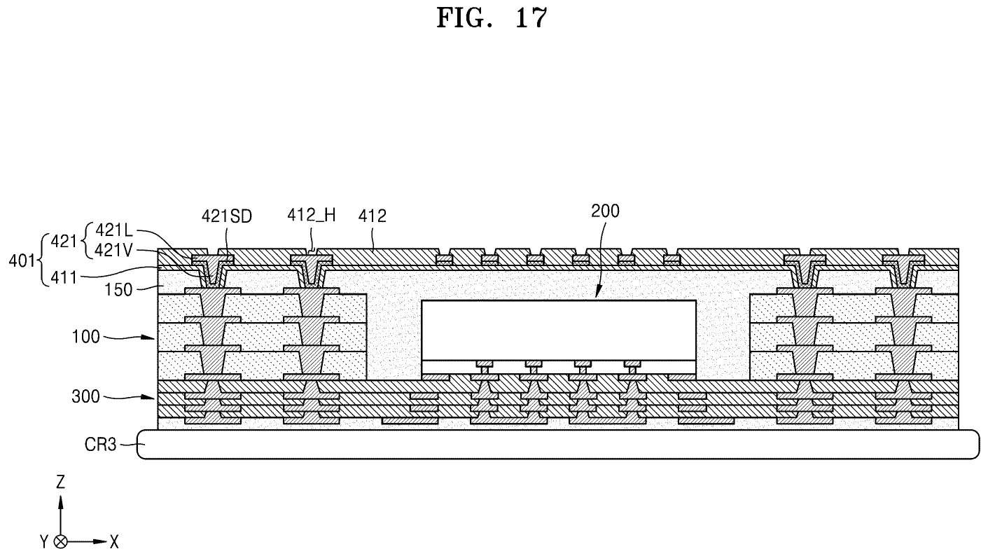

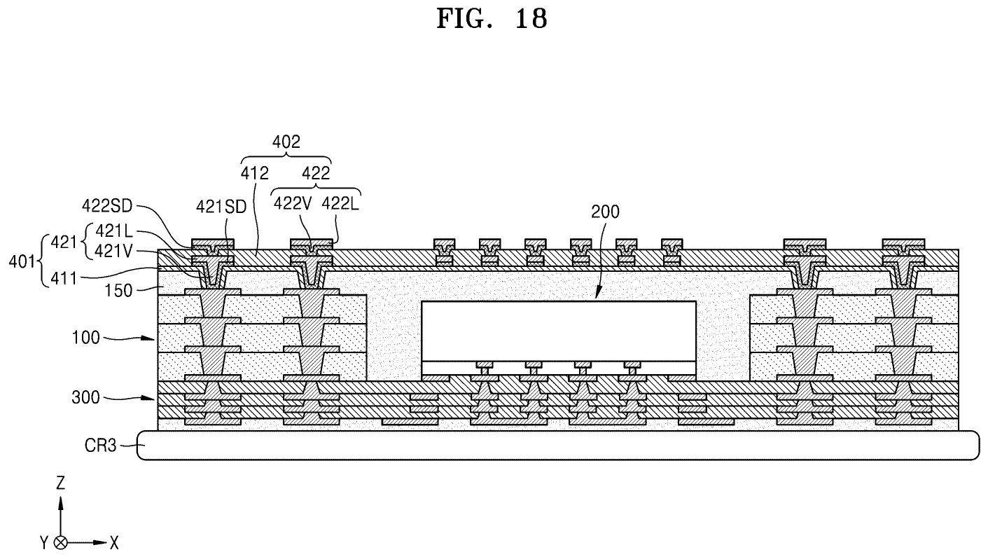

FIGS. 7 to 21 are diagrams showing a method of manufacturing the integrated circuit package 1000 according to a process sequence, according to an embodiment. Referring to FIG. 7, a connection structure 100 and a semiconductor chip 200 may be mounted on a first carrier substrate CR1. The connection structure 100 including a cavity 100_C may be placed on the first carrier substrate CR1. In some embodiments, the connection structure 100 may have a multi-layer structure including a plurality of base layers 110 and include via structures 120 that penetrate each of the plurality of base layers 110 and are electrically connected to each other.

The semiconductor chip 200 may be mounted inside the cavity 100_C of the connection structure 100. The semiconductor chip 200 may include a semiconductor substrate 210 including an active surface 211 and an inactive surface facing the active surface 211 and a wiring structure 220 formed on the active surface 211. For example, the wiring structure 220 of the semiconductor chip 200 may be mounted inside the cavity 100_C such that the semiconductor chip 200 faces the first carrier substrate CR1. In some embodiments, a lower pad 230 formed on the wiring structure 220 of the semiconductor chip 200 may contact the first carrier substrate CR1.

Next, a molding layer 150 may be formed to cover the connection structure 100 and the semiconductor chip 200. For example, the molding layer 150 may fill a space between the connection structure 100 and the semiconductor chip 200 in the cavity 100_C of the connection structure 100, and cover upper surfaces of the connection structure 100 and the semiconductor chip 200. In some embodiments, the molding layer 150 may include ABF, FR-4, BT, EMC, etc.

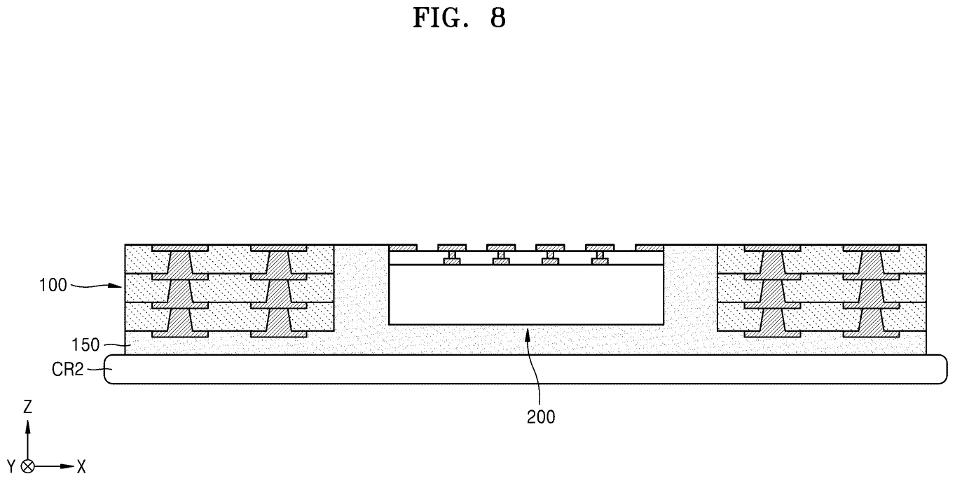

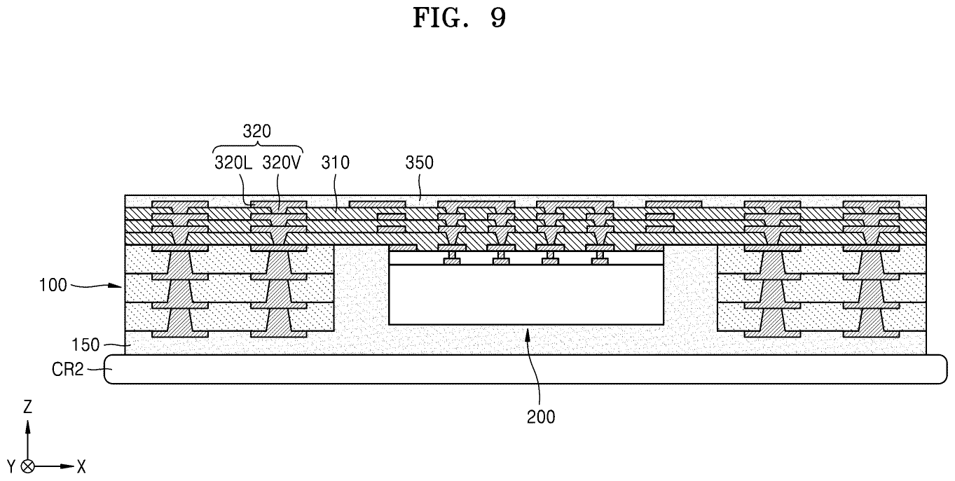

Referring to FIGS. 8 and 9, a lower redistribution structure 300 may be formed on a lower surface of the connection structure 100 and the semiconductor chip 200. A resultant product of FIG. 7 may be flipped and mounted on a second carrier substrate CR2 so that a surface of the molding layer 150 is in contact with the second carrier substrate CR2. Next, the first carrier substrate CR1 may be removed.

Next, the lower redistribution structure 300 may be formed on the connection structure 100 and the semiconductor chip 200 that are exposed to the outside by removing the first carrier substrate CR1. A process of forming the lower redistribution structure 300 may be performed through a redistribution process. That is, through the redistribution process, in the lower redistribution structure 300, a lower insulating layer 310 and a lower via pattern 320V and a lower line pattern 320L included in lower redistribution pattern 320 may be alternately formed. In some embodiments, a lower passivation layer 350 may be formed on the lower insulating layer 310 to protect a portion of the lower redistribution pattern 320.

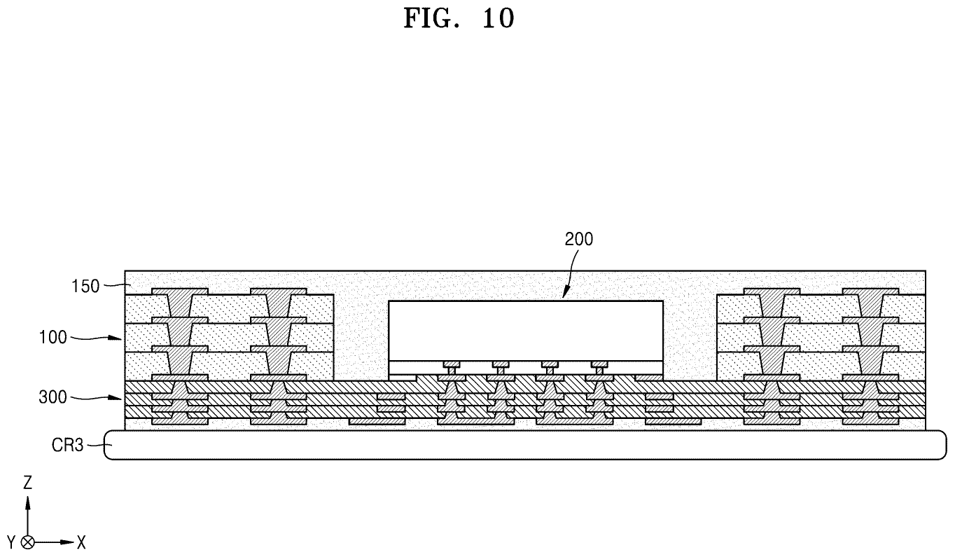

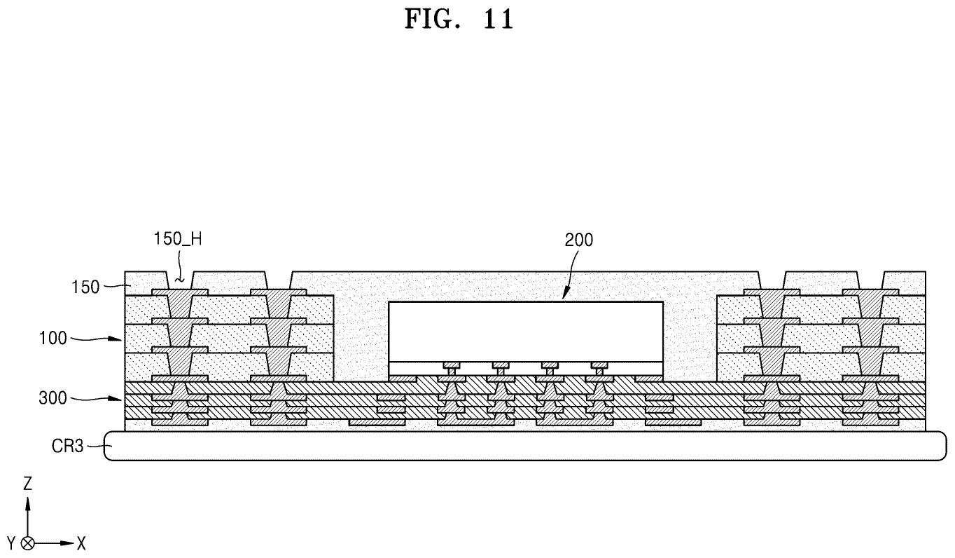

Referring to FIGS. 10 and 11, an upper through hole 150_H may be formed in the molding layer 150. The resultant product of FIG. 9 may be flipped and mounted on a third carrier substrate CR3 such that one side of the lower redistribution structure 300 is in contact with the third carrier substrate CR3. Next, the second carrier substrate CR2 may be removed.

Next, the upper through hole 150_H may be formed on a surface of the molding layer 150 exposed to the outside by removing the second carrier substrate CR2. A portion of the upper through hole 150_H may be formed on the via structure 120 of the connection structure 100. The upper through hole 150_H may extend from an upper surface of the molding layer 150 to the via structure 120 of the connection structure 100. In some embodiments, the upper through hole 150_H may be formed by a laser drilling process. For example, the molding layer 150 may include ABF, and the upper through hole 150_H may be formed by a laser drilling process. Accordingly, a horizontal width of the upper through hole 150_H may be in a range from about 50 μm to about 60 μm.

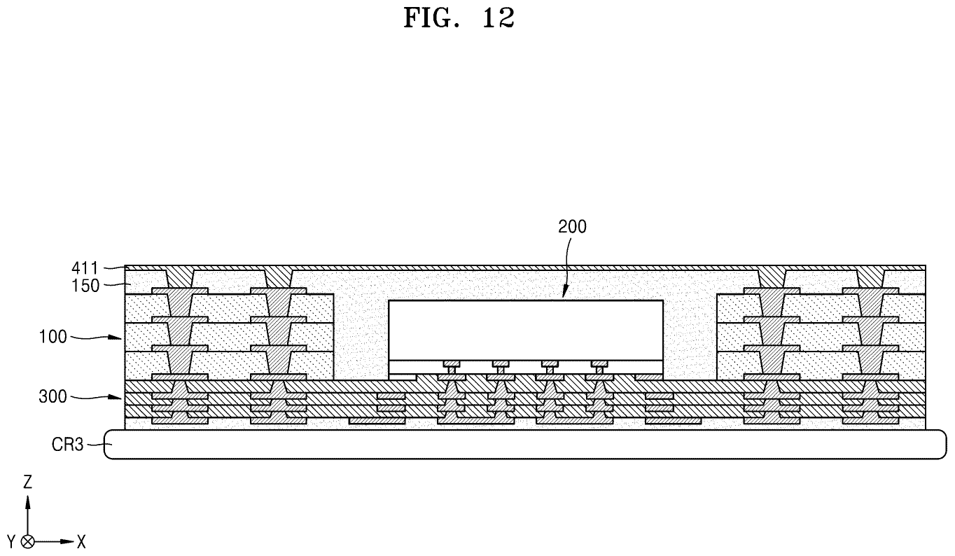

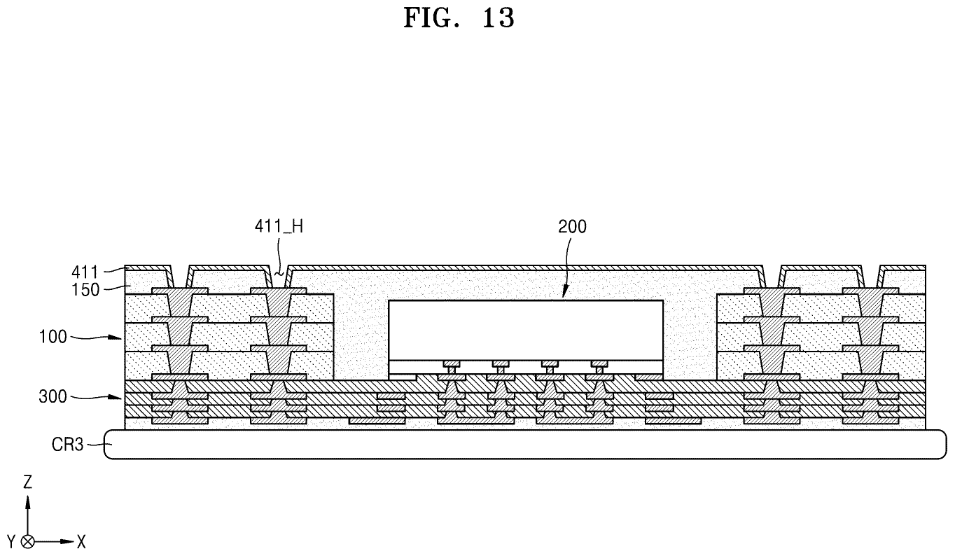

Referring to FIGS. 12 and 13, a first upper insulating layer 411 and a first through hole 411_H may be formed. The first upper insulating layer 411 may be formed to cover the molding layer 150. For example, the first upper insulating layer 411 may fill the upper through hole 150_H of the molding layer 150. In some embodiments, the first upper insulating layer 411 may include an insulating material, for example, a PID resin. In this case, the first upper insulating layer 411 may further include an inorganic filler.

Next, the first through hole 411_H extending from top to bottom of the first upper insulating layer 411 may be formed. The first through hole 411_H may be located inside the upper through hole 150_H. For example, a portion of the connection structure 100 may be exposed to the outside through the first through hole 411_H.

In addition, the first through hole 411_H may be formed through a photo process and an etching process. The first upper insulating layer 411 includes a photosensitive resin, and the first through hole 411_H may be formed through a photo process. Accordingly, a horizontal width of the first through hole 411_H may be in a range from about 10 μm to about 20 μm. That is, the first through hole 411_H may have a less horizontal width than the upper through-hole 150_H.

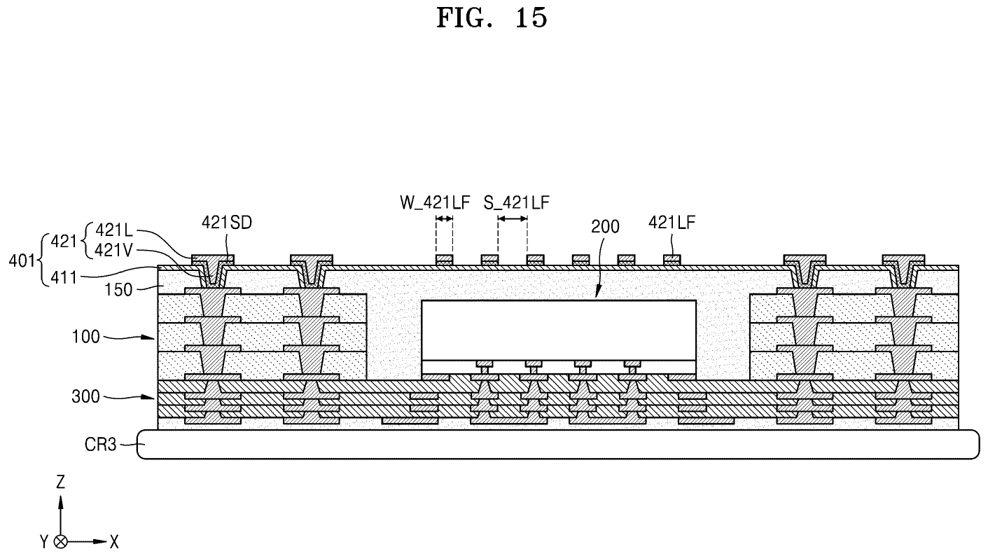

Referring to FIGS. 14 and 15, the first upper redistribution structure 401 may be formed. In the resultant product of FIG. 13, after forming a seed layer 422SD on the first upper insulating layer 411 through a sputtering process, a resist layer PR may be formed. For example, the resist layer PR may include liquid photo resist (LPR).

Next, a portion of the seed layer 421SD on the first upper insulating layer 411 may be exposed to the outside by performing a patterning process onto the resist layer PR. Thereafter, a first upper via pattern 421V may be formed to fill the inside of the first through hole 411_H of the first upper insulating layer 411 through a plating process, and a first upper line pattern 421L may be formed to fill a pattern formed in the resist layer PR. A portion of the seed layer 421SD may be exposed by performing a peeling process of the resist layer PR. The exposed portion of the seed layer 421SD may be removed through an etching process. Another part of the seed layer 421SD may not be exposed to the etching process by the first upper line pattern 421L. Accordingly, after the etching process is completed, another portion of the seed layer 421SD may remain under the first upper line pattern 421L.

In some embodiments, the first fine line pattern 421LF of the first upper line pattern 421L may be formed on the first upper insulating layer 411, a first linewidth W_421LF of the first fine line pattern 421LF may be 3 μm or more and 9 μm or less, and a first line spacing S_421LF may be 3 μm or more and 12 μm or less. For example, a seed layer that forms a basis of the first upper line pattern 421L may be formed through a sputtering process and has a relatively small linewidth/line spacing.

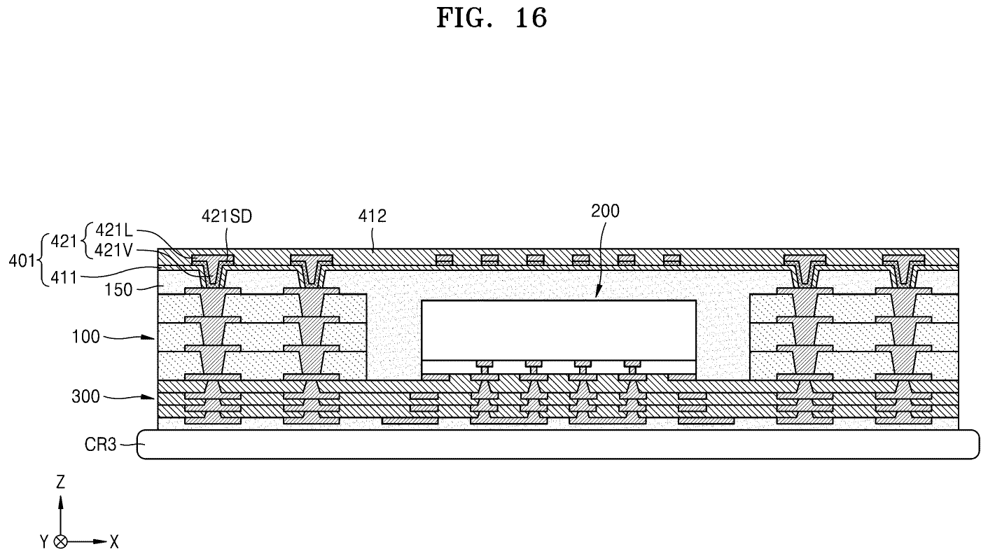

Referring to FIGS. 16 to 18, a second upper redistribution structure 402 may be formed. A second upper insulating layer 412 may be formed on the first upper redistribution structure 401 to cover the first upper redistribution pattern 421. For example, the second upper insulating layer 412 may have the same constituent materials as the first upper insulating layer 411. In some embodiments, the second upper insulating layer 412 may include an insulating material, for example, a PID resin. In this case, the second upper insulating layer 412 may further include an inorganic filler.

Next, after forming the second through hole 412_H extending from an upper surface to a lower surface of the second upper insulating layer 412, a second upper redistribution pattern 422 may be formed. For example, the second through hole 412_H may be formed in the second upper insulating layer 412 through a photo process and an etching process. Accordingly, a horizontal width of the second through hole 412_H may be substantially equal to or less than a horizontal width of the first through hole 411_H.

Next, a seed layer 422SD that serves as a basis of the second upper redistribution pattern 422 may be performed by performing a sputtering process on the second upper insulating layer 412. After forming a resist layer on the second upper insulating layer 412, a portion of the seed layer 422SD on the second upper insulating layer 412 may be exposed to the outside through a patterning process.

Thereafter, a second upper via pattern 422V and a second upper line pattern 422L may be formed to fill a pattern formed on the resist layer of the second upper insulating layer 412 through a plating process. A portion of the seed layer 422SD may be exposed by performing a peeling process of the resist layer. The exposed portion of the seed layer 422SD may be removed through an etching process. Another portion of the seed layer 422SD may not be exposed to the etching process by the second upper line pattern 422L. Accordingly, after the etching process is completed, another portion of the seed layer 422SD may remain under the second upper line pattern 422L.

In some embodiments, the second upper redistribution structure 402 may be formed into a multi-layered structure by repeating the processes of FIGS. 16 to 18.

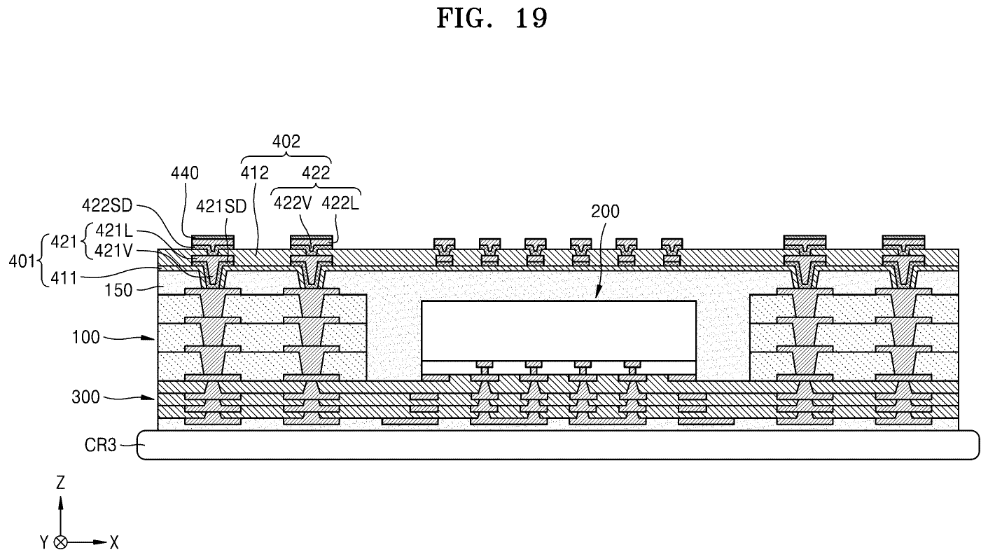

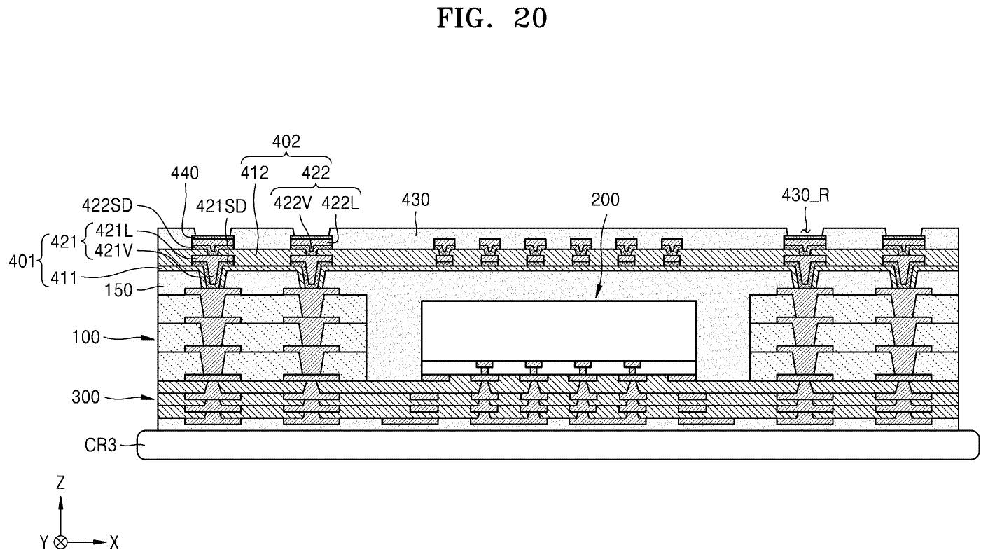

Referring to FIGS. 19 and 20, an upper passivation layer 430 may be formed on the second upper redistribution structure 402. A metal plating layer 440 may be provided on a portion of an upper surface of the second upper line pattern 422L. The metal plating layer 440 may include a metal including, for example, gold (Au). Thereafter, the upper passivation layer 430 may be formed on an upper surface of the second upper insulating layer 412. An opening 430_R may be formed in the upper passivation layer 430 to expose a portion of the second upper redistribution structure 402. The upper passivation layer 430 may protect the first and second redistribution structures 401 and 402. The upper passivation layer 430 may include an insulating material, for example, a thermosetting resin, but is not limited thereto.

Referring to FIG. 21, external connection terminals 340 may be formed on a lower redistribution structure 300. An upper semiconductor chip 500 may be mounted on the upper redistribution structure 400. After forming an upper connection terminal 540 on a lower pad 520 of the upper semiconductor chip 500, the upper connection terminal 540 is located in the opening 430_R of the upper passivation layer 430, and thus, the upper semiconductor chip 500 may be electrically connected to the second upper redistribution pattern 422.

Thereafter, the third carrier substrate CR3 may be removed to expose the lower surface of the lower redistribution structure 300. Afterwards, an opening may be formed in the lower passivation layer 350 so that at least a portion of the lower line pattern 320L is exposed through an etching process or the like. Lower pads 330 may be on the lower line pattern 320L exposed by the opening of the lower passivation layer 350. External connection terminals 340 may be electrically connected to the lower pads 330, respectively.

While the inventive concept has been particularly shown and described with reference to embodiments thereof, it will be understood that various changes in form and details may be made therein without departing from the spirit and scope of the following claims.

What is claimed is:

1. An integrated circuit package, comprising:
a lower redistribution structure;
a connection structure on the lower redistribution structure including a cavity therein
a semiconductor chip within the cavity, and on the lower redistribution structure;
a molding layer that at least partially fills the cavity, and at least partially covers the connection structure and an upper part of the semiconductor chip, the molding layer including an upper through hole therein, which extends inward from an upper surface thereof; and
an upper redistribution structure including: an upper insulating layer on the molding layer, a first protrusion located inside the upper through hole, and an upper redistribution pattern that includes a first upper via pattern located inside the first protrusion;
wherein the upper through hole of the molding layer is above the via structure of the connection structure;
wherein the first upper via pattern is electrically connected to the via structure of the connection structure; and
wherein a portion of the first upper line pattern of the upper redistribution structure is buried in the upper insulating layer.

2. The package of claim 1, wherein the upper via pattern of the upper redistribution structure is at least partially surrounded by the first protrusion, and is spaced apart from the molding layer in a horizontal direction.

3. The package of claim 2, wherein a horizontal width of the first protrusion of the upper insulating layer is in a range from 50 μm to 60 μm, and a horizontal width of the first upper via pattern of the upper redistribution pattern is in a range from 10 μm to 20 μm.

4. The package of claim 1, wherein the horizontal width of the first protrusion of the upper insulating layer narrows in a direction towards the connecting structure; and wherein the horizontal width of the first upper via pattern of the upper redistribution pattern narrows in a direction towards the connection structure.

5. The package of claim 4, wherein a slope of a side of the first protrusion of the upper insulating layer is different from a slope of the first upper via pattern of the upper redistribution pattern.

6. The package of claim 1, wherein a constituent material of the molding layer is different from a constituent material of the upper insulating layer of the upper redistribution structure.

7. The package of claim 1, wherein the molding layer includes a thermosetting resin; and wherein the upper insulating layer of the upper redistribution structure includes a photosensitive resin.

8. The package of claim 1, wherein the upper redistribution structure includes a first upper line pattern and a second upper line pattern buried within the upper insulating layer; and wherein a horizontal level of the first upper line pattern is different from a horizontal level of the second upper line pattern.

9. The package of claim 1,
wherein the upper redistribution structure includes a first upper redistribution structure located on the molding layer and a second upper redistribution structure located on the first upper redistribution structure;
wherein the first upper redistribution structure includes a first upper insulating layer including the first protrusion and a first upper redistribution pattern including the first upper via pattern and the first upper line pattern; and
wherein the second upper redistribution structure includes a second upper insulating layer and a second upper redistribution pattern, which is electrically connected to the first upper redistribution pattern.

10. The package of claim 9, further comprising an upper passivation layer on the upper redistribution structure, wherein the upper passivation layer including an opening therein that exposes a portion of a second upper line pattern of the second upper redistribution pattern.

11. The package of claim 1,
wherein the semiconductor chip includes a semiconductor substrate including an active surface and an inactive surface facing the active surface, and a wiring structure located on the active surface;
wherein the active surface of the semiconductor chip faces the lower redistribution structure; and
wherein the wiring structure is electrically connected to the lower redistribution structure.

12. An integrated circuit package, comprising:
a lower redistribution structure;
a connection structure on the lower redistribution structure and including a via structure;
a semiconductor chip on the lower redistribution structure and horizontally spaced apart from the connection structure;
a molding layer between the connection structure and the semiconductor chip, covering an upper part of the connection structure and the semiconductor chip, and including an upper through hole penetrating the upper surface of the molding layer;
a third upper redistribution structure including a third upper redistribution pattern extending inside the upper through hole and on the molding layer and electrically connected to the via structure, and a third upper insulating layer covering the third upper redistribution pattern;
a first upper redistribution structure including a first upper insulating layer on the third upper redistribution structure, and a first upper redistribution pattern on the first upper insulating layer; and
a second upper redistribution structure including a second upper insulating layer extending on the first upper insulating layer, and a second upper redistribution pattern on the second upper insulating layer;
wherein the constituent material of the third upper insulating layer is different from the constituent material of the first upper insulating layer and the second upper insulating layer;
wherein the third upper insulating layer of the third upper redistribution structure includes a third through hole;
wherein the first upper insulating layer of the first upper redistribution structure further includes a first protrusion located in the third through hole; and
wherein the first upper redistribution pattern of the first upper redistribution structure further includes a first upper via pattern surrounded by the first protrusion.

13. The package of claim 12, wherein the molding layer and the third upper insulating layer of the third upper redistribution structure include a thermosetting resin; and wherein the first upper insulating layer of the first upper redistribution structure and the second upper insulating layer of the second upper redistribution structure include a photosensitive resin.

14. The package of claim 12, wherein a linewidth of a fine line pattern among the third upper redistribution patterns of the third upper redistribution structure is greater than a linewidth of the fine line pattern among the first upper redistribution patterns of the first upper redistribution structure.

15. The package of claim 14, wherein the linewidth of the fine line pattern among the third upper redistribution patterns of the third upper redistribution structure is in a range from 15 μm to 25 μm; and wherein the linewidth of the fine line pattern among the first upper redistribution patterns of the first upper redistribution structure is in a range from 3 μm to 9 μm.

16. The package of claim 12, wherein a horizontal width of the upper through hole of the molding layer is the same as a horizontal width of the third through hole of the third upper insulating layer of the third upper redistribution structure.

17. The package of claim 12, wherein a horizontal width of the third upper via pattern of the third upper redistribution pattern of the third upper redistribution structure narrows towards the connection structure; wherein a horizontal width of the first protrusion of the first upper redistribution structure narrows towards the connection structure; and wherein a slope of the third upper via pattern is the same as a slope of the first protrusion.

18. An integrated circuit package, comprising:
a lower redistribution structure;
a connection structure on an upper surface of the lower redistribution structure, including a via structure, and a cavity therein;
a lower semiconductor chip on the upper surface of the lower redistribution structure and within the cavity of the connection structure;
a molding layer between the connection structure and the lower semiconductor chip in the cavity, covering an upper part of the connection structure and the lower semiconductor chip, and including an upper through hole extending inward from the upper surface thereof;
a third upper redistribution structure including a third upper redistribution pattern on the molding layer and within the upper through hole, and electrically connected to the via structure, and a third upper insulating layer covering the third upper redistribution pattern;
a first upper redistribution structure including a first upper insulating layer on the third upper redistribution structure, and a first upper redistribution pattern on the first upper insulating layer;
a second upper redistribution structure including a second upper insulating layer on the first upper insulating layer, and a second upper redistribution pattern on the second upper insulating layer;
an upper passivation layer on the second upper redistribution structure and including an opening that exposes a portion of the second upper redistribution pattern of the second upper redistribution structure; and
an upper semiconductor chip mounted on the upper passivation layer and electrically connected to the second upper redistribution structure;
wherein the constituent material of the third upper insulating layer is different from the constituent material of the first and second upper insulating layers;
wherein the third upper insulating layer of the third upper redistribution structure includes a third through hole;
wherein the first upper insulating layer of the first upper redistribution structure further includes a first protrusion located in the third through hole; and
wherein the first upper redistribution pattern of the first upper redistribution structure further includes a first upper via pattern surrounded by the first protrusion.

19. The package of claim 18, wherein a horizontal width of the third upper via pattern of the third upper redistribution pattern is in a range from 50 μm to 60 μm; and wherein a horizontal width of the first upper via pattern of the first upper redistribution pattern is in a range from 10 μm to 20 μm.

20. The package of claim 18, wherein a linewidth of the fine line pattern among the third upper redistribution patterns of the third upper redistribution structure is greater than a linewidth of the fine line pattern among the first upper redistribution patterns of the first upper redistribution structure.
